(19) United States
(12) Patent Application Publication
(10) Pub. No.: US 2002/0114202 A1
(43) Pub. Date: Aug. 22, 2002

(54) Method and apparatus for testing memory

(75) Inventors: R. Dean Adams, St. George, VT (US); Michael R. Ouellette, Westford, VT (US); Jeremy P. Rowland, South Burlington, VT (US)

Correspondence Address: IBM MICROELECTRONICS, INTELLECTUAL PROPERTY LAW, 1000 RIVER STREET, 972 E, ESSEX JUNCTION, VT, 05452, US

(73) Assignee: International Business Machines Corporation, Armonk, NY (US)

(21) Appl. No.: 09/736,876

(22) Filed: Dec. 14, 2000

(51) Int. Cl. G11C 7/00

(52) U.S. Cl. 365/201

(57) ABSTRACT

A method and apparatus for testing either or both the row and column decoders of a memory device. Upon selecting the decoder to be tested, the non-selected decoder is locked at a specific location while all possible transitions for the selected decoder are tested.

### BACKGROUND

### TECHNICAL FIELD OF THE PRESENT INVENTION

The present invention generally relates to methods and apparatuses that test memory devices, and more specifically, to methods and apparatuses that test the column and row decoders for such devices.

### BACKGROUND OF THE PRESENT INVENTION

The electronic industry is in a state of evolution spurred by the recent changes in technology which have allowed greater functionality in smaller devices. This has resulted in the explosion of new found uses for such small devices (e.g. medical, monitoring etc.), as well as greater functionality in increasingly smaller electronic devices.

The evolution has caused electronic devices to become an inseparable part of our society. Consumers are now buying and demanding electronic devices which are smaller, more powerful, and faster at unprecedented rates. These demands are constantly driving the electronic industry to exceed limitations which were previously considered unsurpassable, and to identify and resolve problems that had been ignored or not realized.

Memory devices are an example of an area where problems and solutions are in perpetual demand. Memory devices typically have one or more sets each having numerous cells for storing data. The testing of such devices via their individual sets and cells is focused on whether data can be stored and retrieved accurately. This testing typically involves alternating between the reading and writing of various patterns to the memory cell (e.g. writing and reading all zeros, all ones, a checkerboard, inverse checkerboard, etc.).

The testing of the memory cells is only one aspect of the testing for such memory devices. These memory devices typically have column and row decoders for accessing each of the individual cells located therein. These decoders can also have various defects such as open circuits which are not always detectable using the ordinary incrementing and decrementing patterns. FIG. 1 is a schematic diagram illustrating a static AND circuit 100 that is normally employed in most decoders. The circuit 100 includes numerous pfets and nfets and an invertor as shown. PFET 108 is an example of where an open circuit can occur as identified by indicator 108a. As previously stated, the ordinary incrementing and decrmenting type patterns used to go through the memory space still provide the anticipated output at out 106. The inability to detect the open circuit 108 results from the internal node remaining high due to inherent node capacitance. Unfortunately, when the AND circuit 100 is used in random access mode the open circuit 108 will cause a fault. The failure occurs when the internal node is low and only IN2 104 goes low trying to pull up the internal node and drive Out 106 low.

Another defect that can affect the decoders is slow decoder transitions (i.e. the decoder is not responding quick enough). Slow decoder transitions are unacceptable in memory devices. In most cases, unless memories are tested at high speed cycle time, slow transitions are undetectable. In the event that these memories are tested at cycle speed, the slow transition would be detectable, when, and if, every possible transition is provided in between cycles. In memories which use time division multiplexing, where two or more accesses will occur triggered from one external clock edge, the slow transition fault is detectable when, and if, every possible transition is provided between the successive accesses.

It would be a distinct advantage to have a method and apparatus that could test the memory row and column decoders for the various problems noted above. The present invention provides such a method and apparatus.

### SUMMARY OF THE PRESENT INVENTION

The present invention is a method and apparatus for testing either or both the row and column decoders of a memory device. Upon selecting the decoder to be tested, the non-selected decoder is locked at a specific location while all possible transitions for the selected decoder are tested.

### BRIEF DESCRIPTION OF THE DRAWINGS

The present invention will be better understood and its numerous objects and advantages will become more apparent to those skilled in the art by reference to the following drawings, in conjunction with the accompanying specification, in which:

FIG. 1 is a schematic diagram illustrating a static AND circuit 100 that is normally employed in most decoders;

FIG. 2 is a schematic diagram illustrating an example of the internal components of a memory device;

FIG. 3 is a schematic diagram illustrating in greater detail a sub-array of the memory array of FIG. 2; and

FIG. 4 is a flow chart illustrating the steps for implementing the testing of either the row or column decoder of FIG. 3 according to the teachings of the present invention.

### DETAILED DESCRIPTION OF THE PREFERRED EMBODIMENT OF THE PRESENT INVENTION

In the following description, numerous specific details are set forth such as specific word or byte lengths, etc., to provide a thorough understanding of the present invention. However, it will be obvious to those of ordinary skill in the art that the present invention can be practiced with different details. In other instances, well-known circuits have been shown in block diagram form in order not to obscure the present invention in unnecessary detail. For the most part, details concerning timing considerations and the like have been omitted inasmuch as such details are not necessary to obtain a complete understanding of the present invention, and are within the skills of persons of ordinary skill in the relevant art.

FIG. 2 is a schematic diagram illustrating an example of the internal components of a memory device 200. Memory device 200 includes row and column decoders 206 and 204, and memory array 202. Memory array 202 has been subdivided into multiple sub-arrays 202a-d in order to better facilitate the testing of the decoders 204-206. The column and row decoders 204 and 206 are used for selecting a specific memory location within each of the arrays 202a-d.

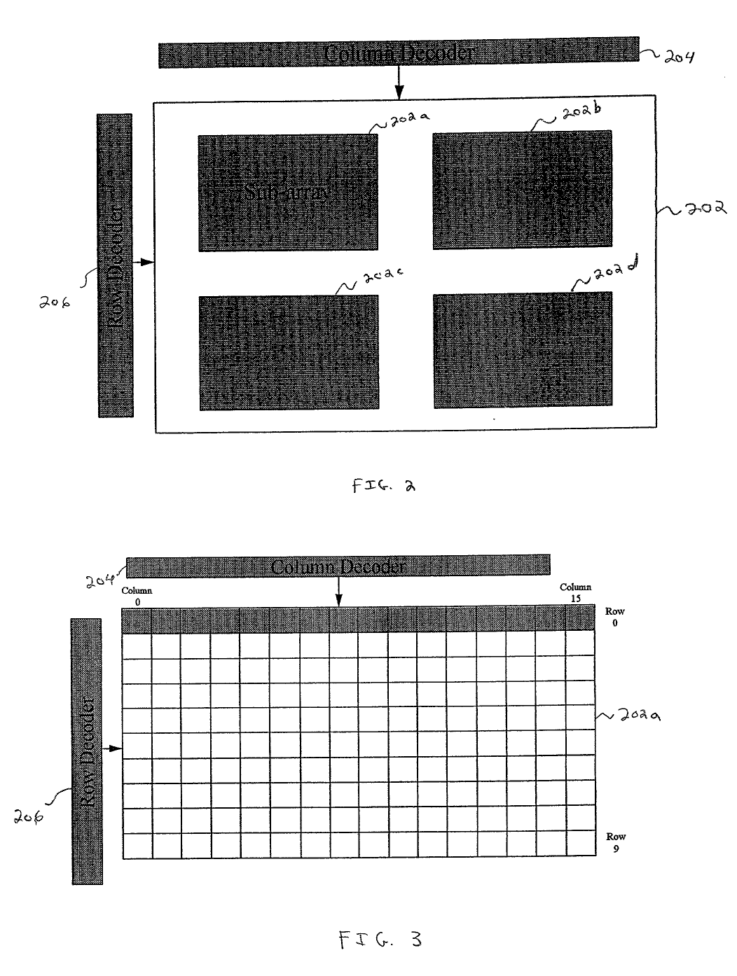

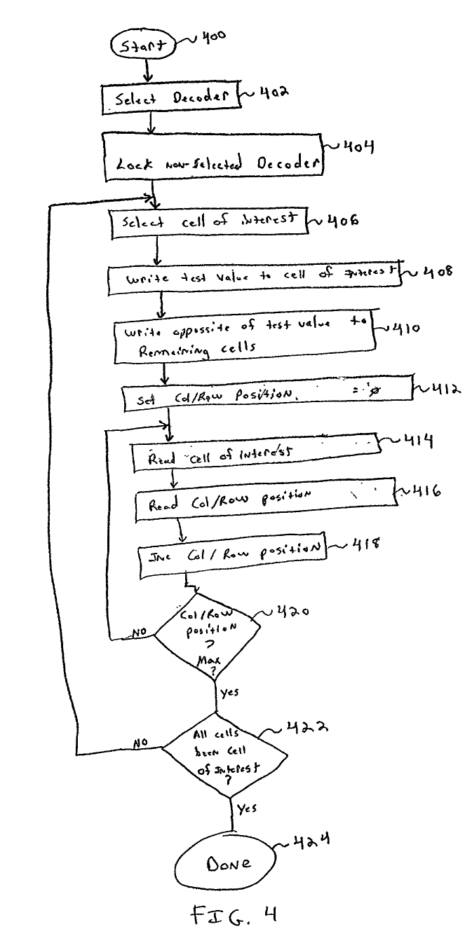

FIG. 3 is a schematic diagram illustrating in greater detail sub-array 202a of memory array 202 of FIG. 2. Sub-array 202a is representative of sub-arrays 202b-d, and therefore, the discussion with respect to sub-array 202a is equally applicable to sub-arrays 202b-d. In order to better explain the novelty and various advantages of the present invention, sub-array 202a has been illustrated as having multiple memory cells in a two dimensional format (i.e. rows and columns). The present invention is not, however, intended to be limited to any particular dimensional format. In this particular format, sub-array 202a has 16 columns (0-15) and 10 rows (0-9).

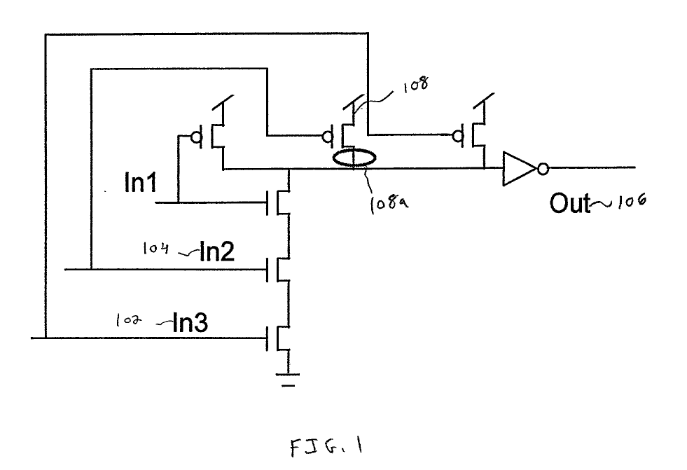

The present invention tests the row and column decoders 206 and 204, respectively, for open circuits that are similar in nature to that illustrated and explained in connection with FIG. 1, and for slow-to-transition faults. The testing is accomplished by focusing on only one of the decoders 206 or 204 at a time and testing all possible transitions for the selected decoder using an Nˆ 2 pattern. Specifically, if the column decoder 204 is to be tested, then the row decoder 206 is locked on a specific position such as 0 while all possible transitions of the column decoder 204 are tested, such that N=16.

The testing of the column decoder proceeds as follows:

1. select one of the cells “cell of interest” (e.g. 0);

2. write a “1” to the cell of interest and 0s to all of the remaining cells (e.g. 2-15);

3. read the value of the cell of interest and starting at column X read its value where X is initially 0;

4. repeat step 3 and increment the value of X until the values of the remaining columns (e.g. 1-15) have been read.

5. select a different cell of interest (e.g. 1) and repeat steps 1 to 4 above until all cells have been tested.

Table 1 below represents pseudo code for implementing the steps noted above.

TABLE 1

row address is set to 0s
write “0” to all columns
for cellofinterest = 0..15
{

write a “1” to cellofinterest;
for columnposition = 0..15
{

if columnposition = cellofinterest then{
read 1 cellofinterest, read 1 cellofinterest;
}
else {
read 1 cellofinterest, read 0 column position
}

}
write a “0” to cellofinterest;
cellofinterest = cellofinterest + 1

}

Once the above pseudo code has been executed the testing of the column decoder 204 is complete, and it is not necessary to test any other rows.

The testing of the row decoder 206 proceeds in the same way as the testing of the column decoder, in that the column decoder is locked while all possible row transitions are tested. It should be noted and appreciated that most of the address space has not been used, yet all possible transitions have occurred for each individual decoder. The above description illustrated read to read transitions, however, the present invention can also be used with write to read transitions as well.

FIG. 4 is a flow chart illustrating the steps for implementing the testing of either the row or column decoder 206 or 204 according to the teachings of the present invention. The process begins by selecting a decoder for which the testing will occur (steps 400-402). Once the decoder has been selected, then the non-selected decoder is locked on specific position (e.g. column decoder selected, row decoder locked at row 0) (step 404). The process proceeds by selecting a cell for which a unique value will be written “test value” and writing a value to the cell of interest (steps 406-408) (e.g. cell 1 and the test value being “1”). The process continues by writing a value that is opposite to that of the test value to the remaining cells (step 410). The column/row address value of the decoder being tested is initially set to 0 (e.g. col 0 if column decoder 204 is being tested) (step 412). the process proceeds by reading the value from the cell of interest, and then reading the value from the cell pertaining to the column/row address value (steps 414-416). The value of the column/row address is then incremented (step 418). A determination is then made concerning whether all of the column/row address locations have been read (i.e. max value for such position exceeded (e.g. max value for col is 15)) (step 420).

If the maximum value of the column/row address has not been exceeded, then the process proceeds back to step 414 and repeats the steps from that point again. If, however, the maximum value of the column/row address has been exceeded, then the process continues by determining whether all of the cells in either the row or column have at one point in the process been assigned as the cell of interest (step 422). If all the cells have not yet been appointed as the cell of interest, then the process proceeds back to step 406 and repeats the steps from that point again. If, however, all of the cells have at one point in the process been appointed as the cell of interest, then the process proceeds to end at step 424.

It is thus believed that the operation and construction of the present invention will be apparent from the foregoing description. While the method and system shown and described has been characterized as being preferred, it will be readily apparent that various changes and/or modifications could be made wherein without departing from the spirit and scope of the present invention as defined in the following claims.

What is claimed is:

1. A method for testing a column or row decoder of a memory device, the method comprising the steps of:
selecting a row or column of the memory device; and
testing all possible transitions for each of the cells in each of the columns of the selected row or rows of the selected column.
